(19) United States
(12) Patent Application Publication
(10) Pub. No.: US 2010/0148789 A1
(43) Pub. Date: Jun. 17, 2010

(54) System for Measuring the Electric Potential of a Voltage Source

(76) Inventors: Andrew D. Hibbs, La Jolla, CA (US); Micheal Andrew Krupka, San Diego, CA (US); Robert Matthews, San Diego, CA (US); Linas Kunstmanas, Valley Center, CA (US)

Correspondence Address: DIEDERIKS & WHITELAW, PLC, 13885 HEDGEWOOD DR., SUITE 317, WOODBRIDGE, VA, 22193, US

(21) Appl. No.: 11/992,309

(22) PCT Filed: Sep. 22, 2005
(86) PCT No.: PCT/US2005/034003

§ 371 Date: Mar. 20, 2008

(51) Int. Cl. G01N 27/02; G01R 19/00

(52) U.S. Cl. 324/445; 324/123 R

(57) ABSTRACT

A non-invasive measurement system (110) for measuring the electrical potential of a voltage source (20, 120) includes a sensing electrode (50, 151) spaced from the voltage source (20, 120). Preferably the voltage source (20, 120) is within a biological cell (115) located in a nutrient bath (119) including electrolytic medium (117) and an object (30, 190) is a portion of the electrolytic fluid (117) located between the cell (115) and the sensing electrode (50, 151). A feedback electrode (181) is formed in an annular shape and surrounds the sensing electrode (50, 151) thus creating an annular fluid region therebetween. The value of the voltage in the annular region (131) is set substantially equal to the value of the voltage in the object (190) and therefore the impedance between the object (190) and a stray voltage source (40) is maximized.

### BACKGROUND OF THE INVENTION

1. Field of the Invention

The present invention pertains to the art of electrical sensing devices and, more particularly, to a system having a high electrical impedance that measures the electrical potential of a voltage source.

2. Discussion of the Prior Art

The measurement of the electrical potential of an object, or region, in a conducting medium can be difficult when the element that senses the potential couples to the object with an electrical impedance that is comparable to or higher than other impedances coupled to the object. This situation arises when the sensing is predominantly capacitive and in cases when the sensing element is very small. For example, such situations arise in electrophysiology measurements used in biological research, sensing in a fluid medium, and the control of voltages in processes that involve a conducting fluid or medium.

Accurate measurements of electric potentials in fluid environments are made difficult by the conductivity of the fluid. A particular example is the measurement of the internal electrical potential of cells suspended in a fluid, which is important for basic biological research, pharmaceutical drug development, and for a number of other diagnostic or sensing purposes. These measurements are typically made using patch clamp techniques, which access an internal potential of cells by penetration of a cell's membrane using a resistive electrode. In some cases, electrical access is gained by making the membrane locally permeable. Traditionally, these patch clamp methods have been accomplished by individuals using very labor intensive techniques that permit only one cell to be measured at a time. Modern techniques for making these measurements at higher throughput and reliability have focused on robotic or otherwise pseudo-automated techniques for reducing the labor required. These techniques have met with limited success because the basic requirement of membrane penetration (or permeation) remains.

An attempt has been made to address this limitation by making an electrical measurement without disrupting the cell membrane, as disclosed by Fromherz, et al. Fromherz's work focused on the use of a capacitively based measurement of the internal cell potential changes through measurement of an intermediate layer of fluid. This technique has the advantage that it does not disrupt the cell membrane and permits extended measurement over time as well as other possible advantages. While Fromherz's work shows that the basic concept of capacitively based assessment of internal cell potential is feasible, his measurements of the intermediate layer are unreliable and complicated by stray electrical coupling to other elements in the overall system. Therefore, the technique cannot be used to reliably infer the internal potential of a cell. This severely limits practical implementation of Fromherz's technique or of any method relying on only a sensing electrode.

Based on the above, there exists a need in the art for a measurement system for measuring the electrical potential of a voltage source that reduces stray electrical coupling to other elements in the system. Further such a system should be able to accurately and reliably measure the electrical potential of the voltage source.

### SUMMARY OF THE INVENTION

The present invention is directed to a non-invasive measurement system for measuring an electrical potential of a voltage source. The system includes a sensing electrode spaced from the voltage source, as well as an object placed between the electrode and the voltage source. Further a feedback electrode is positioned near the sensing electrode. An amplifier is provided with an input connected to the sensing electrode with a first low resistance connection and an output connected to the feedback electrode with a second low resistance connection.

In accordance with a preferred form of the invention, the voltage source is within a biological cell located in a nutrient bath including electrolytic fluid and the object is the boundary layer of proteins and a portion of the electrolytic fluid that surrounds the cell, between the cell and the sensing electrode. The sensing electrode is preferably connected to the voltage source by a capacitive connection but may be connected by a resistive connection. Likewise the feedback electrode is preferably connected to the voltage source by a capacitive connection but may be connected by a resistive connection.

The feedback electrode is formed in an annular shape and substantially surrounds the sense electrode thus creating an annular fluid region therebetween. The amplifier has an input impedance and the coupling of the sense electrode to the object has an impedance. The amplifier has a gain set to compensate for an impedance dividing effect of the amplifier's input impedance and the impedance of the coupling to the sensing electrode, as well as to compensate for the drop in voltage from the feedback electrode to the electrolyte solution surrounding it. The value of the voltage in the annular region is set to be substantially equal to the value of the voltage in the object, while the impedance between the object and a stray voltage source is maximized. The value of the impedance between the sensing electrode and the feedback electrode is set by the physical spacing between them.

In use, the noise present while measuring an electric potential of a biological cell located in a nutrient bath may be reduced by sensing the electrical potential through an object with a sense electrode and maximizing the impedance between the object and any other source of voltage by using the feedback electrode to set the voltage of the electrolyte in the annular space substantially equal to the voltage of the object. Such a method improves the measurement of the electrical potential of a biological system by making the measurements less sensitive to stray coupling or electrical shunts to other elements in the system.

Additional objects, features and advantages of the present invention will become more readily apparent from the following detailed description of a preferred embodiment when taken in conjunction with the drawings wherein like reference numerals refer to corresponding parts in the several views.

### BRIEF DESCRIPTION OF THE DRAWINGS

FIG. 1 is a schematic showing the elements of the measurement problem addressed by the invention;

FIG. 2 shows a cell in an aqueous electrolytic medium situated above a capacitive sensing electrode and a feedback electrode;

FIG. 3 is a schematic circuit diagram of the measurement system;

FIG. 4a is a circuit diagram for modeling the measurement system;

FIG. 4b is another circuit diagram for modeling the measurement system;

FIG. 5 is a graph showing the response of a measuring system in accordance with the preferred embodiment of the invention having an active feedback versus a measurement system not having active feedback;

FIG. 6a is a graph showing the response of the measuring system with no feedback; and to FIG. 6b is graph showing the response of the measuring system with feedback.

### DETAILED DESCRIPTION OF THE PREFERRED EMBODIMENT

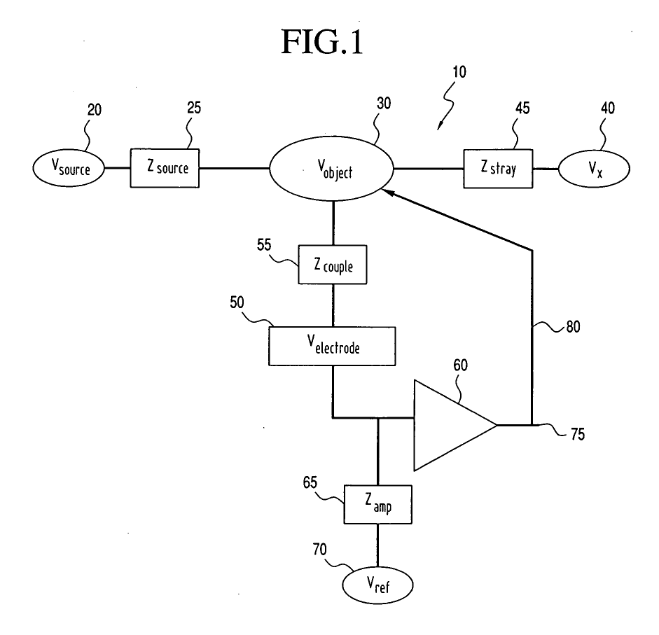

With initial reference to FIG. 1, the basic elements of the measurement problems to be addressed according to the invention is schematically shown at 10. A voltage source 20 producing voltage having a value V_{source} is shown with an associated impedance 25 having a value Z_{source}. An object 30 has a voltage V_{object} due to coupling to source 20. The “object” means a region of approximately equal electric potential, the boundaries of which are set by the physical configuration of the measurement problem. Object 30 could be a charged body, or could be a body of material held at a voltage via capacitive coupling to a local potential. In one case, where the ultimate goal is to measure V_{source}, one may be constrained by the physical aspects of the problem to measuring the voltage V_{object} of object 30. For example, one may desire to measure the internal potential of a cell via an external electrode as in the work of

Fromherz et al., and object 30 could be the boundary layer of proteins and water that surrounds the cell. In another case, a system may be arranged such that V_{object} itself is the primary variable of interest and V_{object} is maintained relative to the V_{source} by the action of Z_{source}, e.g., by a current to flowing through Z_{source}. In either case, coupling of an electrode to intermediate object 30 or to the source 20 itself is complicated by the presence other potentials 40 having a voltage value (Vₓ) in the system and associated stray coupling 45 having an impedance value Z_{stray}.

A sense electrode 50 is coupled to object 30 to be measured via impedance Z_{couple}. Electrode 50 is also coupled to a reference potential 70 V_{ref} of a circuit used to measure the potential V_{electrode} of electrode 50 via a coupling 65 having an input impedance Zₐₘₚ of a first stage amplifier 60. Amplifier 60 has an output 75. Object 30 can never be fully isolated from its environment and, even in the limiting case of zero resistive coupling, it will still have a capacitive coupling 45 to its surroundings 40 at some potential Vₓ. This residual coupling 45 has a value represented by Z_{stray}.

The voltage of object 30, V_{object}, will depend on V_{source}, the impedance to object 30, Z_{source}, and the values of Z_{couple}+Zₐₘₚ and Z_{stray}. For example, if Z_{stray} is small compared to the other impedances, then V_{object} will be very similar to Vₓ, and will have a correspondingly weaker relationship to V_{source}. A similar effect will occur if Z_{couple}+Zₐₘₚ is small, but this can in general be minimized by design of Zₐₘₚ. Ideally, Z_{source} is small so that V_{object} is not affected significantly by the other impedences, and Z_{couple} is small so that V_{electrode} differs little from V_{object}.

The ratio of the potential of object 30 and electrode 50 can be calculated from simple electrical circuit theory if the impedances are known. Zₐₘₚ is generally straightforward to measure, and electrode 50 can be designed to have a known value of Z_{couple}. However, in many cases of practical interest, Z_{couple} will be high owing to the small size of o object 30 and other considerations. In these cases it is very important that Z_{stray} also be arranged to be high so as to provide a measurable signal. In general, it is difficult to control Z_{stray} when the physical size of object 30 is small, and/or when fluids are involved, as in a biological system. The present invention provides a feedback means 80 to make V_{object} and therefore V_{electrode} less dependent on the value of Z_{stray}.

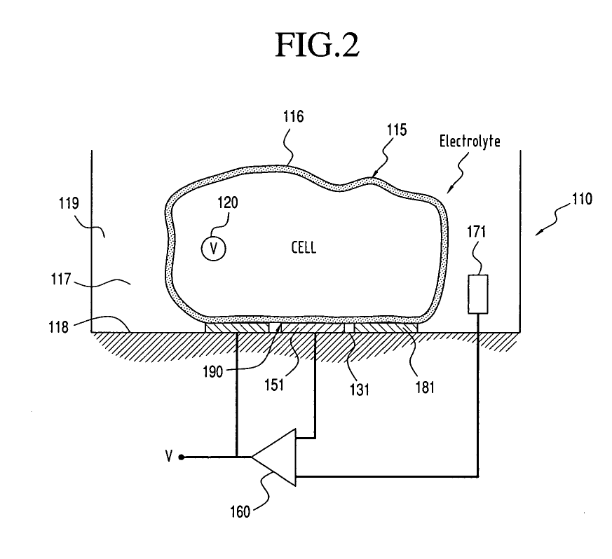

The non-invasive measurement system 110 of the present invention will now be further described with reference to FIG. 2. A cell 115 having a cell membrane 116 resides in an electrolytic bath 117 having a bottom surface 118, that is an insulating substrate, and containing an electrolytic medium 119. Cell 115 is shown having an internal voltage source 120 relative to bath 117. An annular shaped volume 131 of electrolytic solution is formed around a sensing electrode 151. A reference electrode 171 provides a reference voltage and a feedback electrode 181 substantially surrounds volume 131. The top of sensing electrode 151 is covered with a biological adhesive layer, such as polylysine, collagen, fibronectin, supported or tethered bilayer, or similar material, so as to anchor cell 115 as its potential is measured. A sensing region (object 190) of cell 115 is positioned between the body of cell 115 and sensing electrode 151 and is comprised of proteins attached to cell membrane 116 and permeated by electrolyte medium 119 that otherwise surrounds cell 115 in bath 117. Object 190 to be measured is actually the volume of electrolyte medium between the bottom of cell 115 and the top of sensing electrode 151, and includes part of cell membrane 116.

Annular volume 131 beneath cell 115 and around sensing electrode 151 is an electrically conducting path to the remainder of the electrolyte medium 119 in bath 117 and comprises stray coupling 45 having the impedance value Z_{stray} of FIG. 1. The thickness of electrolyte medium 119 between cell 115 and sensing electrode 151 is preferably made as thin as possible to maximize the value of Z_{stray}. In general, the thickness of annular volume 131 is not controllable and varies significantly for repeated attachments of even the same cell type. A principal purpose of the invention is to minimize the effect of variations in Z_{stray}. However, while the resistive path of electrolyte medium 119 under cell 115 in the lateral direction is key, its value in the normal direction is negligible compared to the other impedances. Thus, changes in electrolyte medium thickness have a negligible effect on Z_{couple}.

Depicted in FIG. 2 is a feedback electrode 181 surrounding sensing electrode 151. The potential of feedback electrode 181 is controlled by active electronics. The purpose of feedback electrode 181 is to control the potential of the electrolyte medium 119 in its immediate vicinity such as the annular volume 131. Thus feedback electrode 181 operates in a manner analogous to a guard used to minimize stray capacitance in a shielded coaxial cable. The specific difference is that, whereas in a cable the potential of the inner conductor can be easily measured by a low impedance connection and the potential of the outer conductor can be easily controlled via a direct low impedance electrical connection, in the scope of the present invention neither low impedance connection can be made. A further difference is that, in the cable, the impedance between the inner and outer conductor (i.e. Z_{stray}) is much higher that the connections that can be made to the inner (i.e. Z_{couple}) and outer conductors of the cable.

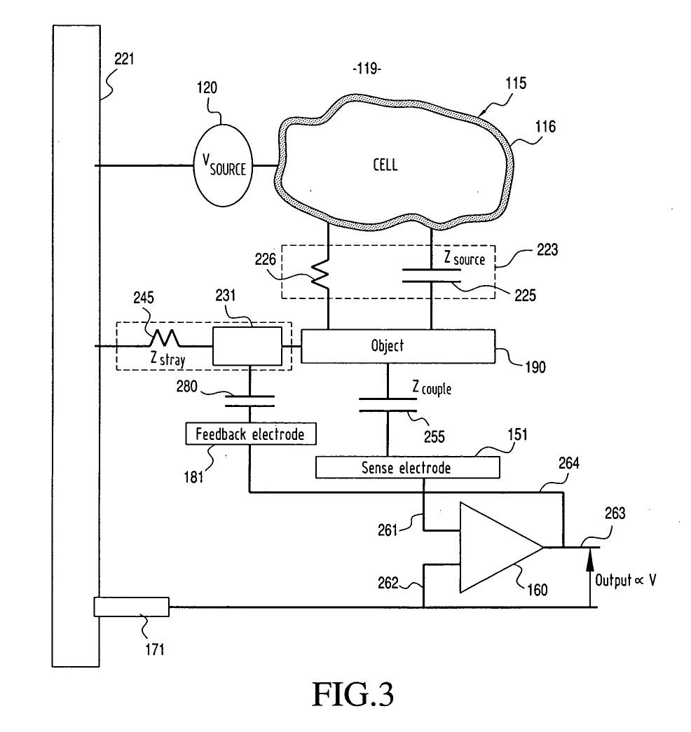

The principal circuit elements of the invention are shown in FIG. 3. To maintain the normal function of cell 115, electrolyte medium 119 comprises a solution of ions and has high electrical conductivity compared to other circuit impedances. Accordingly, it is convenient to define all potentials relative to electrolyte medium 119 and the voltage of medium 119 is represented as ground 221. The body of cell 115 is connected with coupling 223 to object 190 via capacitance 225 and resistance 226 of the cell's phospholipid bilayer membrane 116 that separates them. In this preferred embodiment, the sensing and feedback electrodes 151 and 181 are coupled capacitively, and an amplifier circuit 160 is referenced to electrolyte medium 119 via electrode 171. The remaining electrolyte-to-electrode coupling elements can be coupled to electrolyte medium 119 either resistively or capacitively, but greater stability is generally achieved with a resistive connection. Because the circuit reference electrode 171 can be located far from cell 115, electrochemical effects associated with faradaic coupling are much less of a concern than for sensing electrode 151. To reflect the reduced size constraint, amplifier reference electrode 171 is shown schematically as an immersed cylindrical electrode in FIG. 3. Sensing electrode 151 is shown coupled to object 190 via a capacitive connection only. This is preferable because maintenance of a resistive (i.e. galvanic, faradaic) connection requires ionic exchange with a soluble electrode which can lead to undesirable concentration gradients in electrolyte 117 medium or other system reliability or lifetime problems. However, it will be appreciated that, for some cellular measurements, a resistively coupled electrode might be preferable, and such electrodes might in general be preferred for other measurements (e.g. ones that are not significantly affected by concentration changes). Feedback electrode 181 can be capacitively or resistively coupled to electrolyte medium 119 with which it is in contact, with capacitive coupling being the preferred embodiment. In the case that an electrode with primarily resistive coupling is used, a blocking capacitor (not shown) can be placed in series with the electrode to prevent the flow of a DC current. Object 190 is shown as having a separate part 231 connected to ground 221 through a resistor 245 representing stray impedance Z_{stray}.

In most applications the value of other impedances (e.g. Z_{couple} and Z_{stray}) are high and so the potential of sensing electrode 151 must be measured by a high-impedance amplifier 160. The gain of amplifier 160 is set so as to compensate for the impedance dividing effect of its input impedance and a coupling 255 of sensing electrode 151 to object 190, and also to compensate for the drop in voltage from feedback electrode 181 to the electrolyte medium 119 in its immediate vicinity due to coupling impedance 280. Amplifier 160 has an input 261 from sensing electrode 151 and is also connected through a line 262 to ground 221 through electrode 171. Amplifier 160 also has an output 263 which sends a signal to be measured and is also connected via line 264 to feedback electrode 181. The function of amplifier 160 and the feedback components is thus to create a voltage in the annular volume 131 that is equal to the voltage of object 190. Note that feedback electrode 181 is connected through capactive coupling 280 through-medium 119 to separate object part 231.

By this system there is a minimal voltage difference between object 190 and the annular region 131 that surrounds it, with this voltage difference being ideally zero. By this method the effective impedance between object 190 and any other source of potential (i.e. Z_{stray}) is maximized.

In order to set the feedback section transfer function correctly, the calibrations need to be performed to determine the feedback electrode and sensing electrode coupling capacitances. This is preferably done by driving the electrolyte bath with a signal (with no cell present) while measuring the signal on sensing electrode 151. From this the sense electrode capacitance can be measured and the capacitance per unit area can be calculated, thus allowing the feedback electrode capacitance to be calculated. The stray impedance (Z_{stray}) can be determined by driving electrolyte bath 117 with cell 115 present while measuring sensing electrode 151.

An important feature of the design of sensing electrode 151 and feedback electrode 181 is to ensure a sufficiently high impedance between them to prevent an increase in overall system noise. In the case of cell 115, this impedance is determined by the electrodes' respective coupling to electrolyte medium 119 and the impedance of the medium itself, and can be controlled by ensuring an adequate physical spacing of electrodes 151 and 181.

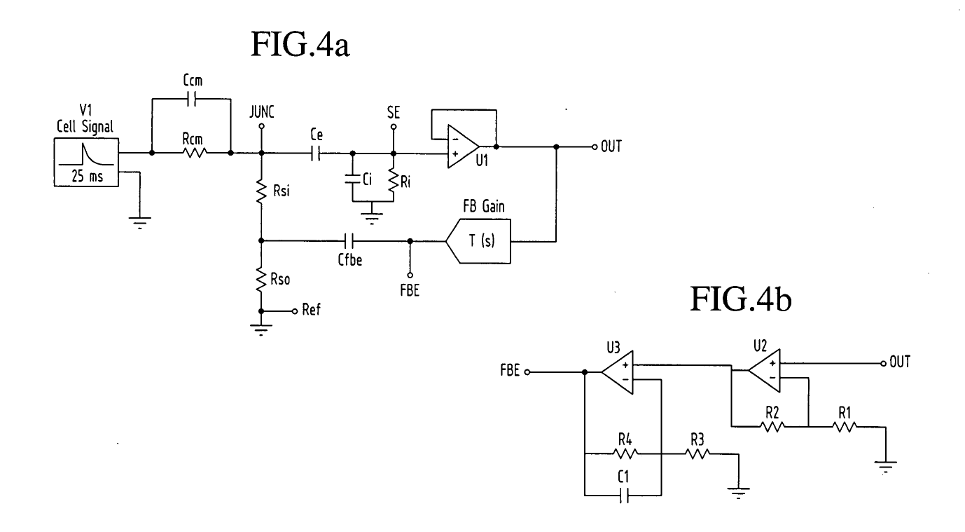

In FIG. 4a cell 115 is represented by an action potential V1 and membrane capacitance Ccm and resistance Rcm which connects to object 190 of which the potential is sensed, represented by the junction node JUNC. Junction node JUNC connects to the readout amplifier U1 with input capacitance and resistance Ci and Ri through the coupling capacitance Ce of the sense electrode node SE. The junction node also connects to the reference node REF through the stray impedance Rsi and Rso. The feedback electrode capacitance Cfbe connects the feedback electrode node FBE to the stray impedance Z_{stray}. The stray impedance is represented by two parameters, the inner seal resistance Rsi, which is the resistance between the junction above sense electrode 154 and the region above feedback electrode 181, and the outer seal resistance (Rso), which is the resistance from the region above feedback electrode 181 to remainder of electrolytic bath 117. The section, FB Gain, indicated by transfer function T(s) is an active circuit that accommodates for the loss in the sense electrode coupling and the loss in the feedback electrode coupling.

In the simplest case T(s) would be given by

$$T ( s ) = {g}_{dc} ( 1 + \frac{1}{s \cdot τ} )$$

where s is the Laplace variable, τ is given by Rso·Cfbe , and g_{dc} is by (Ce+Ci)/Ce. This is essentially a non-inverting integrator with a fixed gain term. Unfortunately this transfer function is not realizable, because it goes to infinity at dc, or is unstable when used in the feedback path, because of the positive feedback. A more realizable function is given below

$$T ( s ) = {g}_{dca} ( 1 + \frac{1}{s \cdot τ + {g}_{dci}} )$$

where g_{dci} is the dc gain of the integrator stage and g_{dca} is close to but less than (Ce+Ci)/Ce.

FIG. 4b shows a realizable circuit for T(s) given by the proceeding equation where, τ=R3·C1=Rso·Cfbe, 1+R2/R1<(Ce+Ci)/Ce, and g_{dci}=R4/R3.

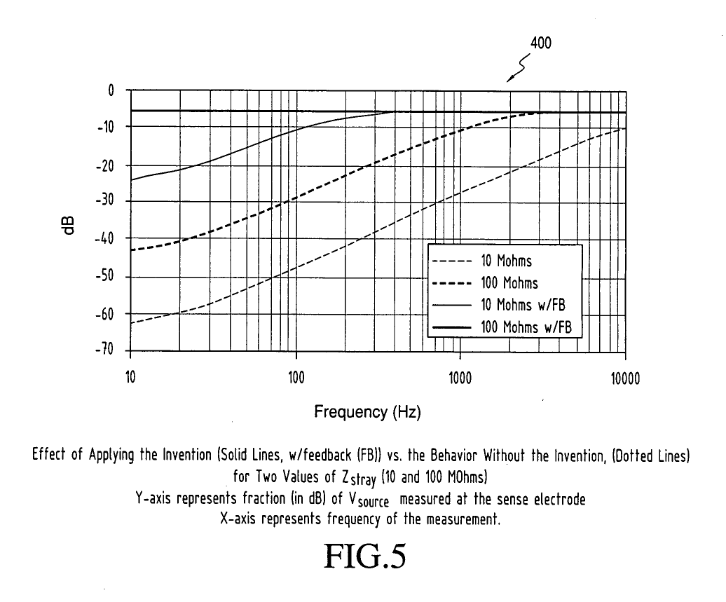

The response 400 of the system for two values of Z_{stray} is shown in FIG. 5. Because of the combination of resistive and reactive elements inherent in the general case, the coupling between sensing electrode 151 and the cell voltage depends on frequency. The fraction of the signal measured at sensing electrode 151 without feedback is shown as the dotted lines. The solid lines depict the benefit of applying feedback voltage to control the potential of the electrolyte medium as previously described. It can be seen that the effect of the invention is to make the is amplitude of the measured signal much less dependent on frequency.

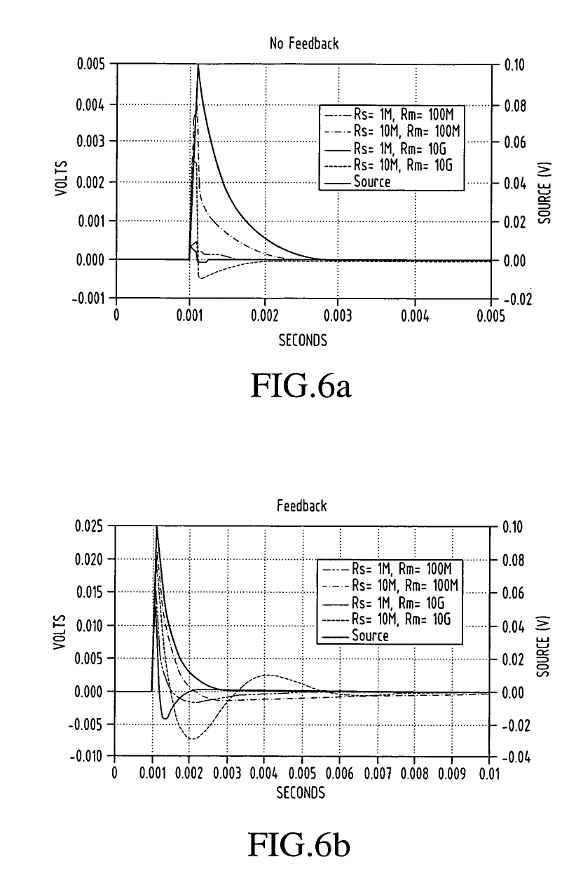

A comparison of the internal cell potential with that recorded by sensing electrode 151, with and without the benefit of feedback as taught by the present invention, is shown in FIGS. 6a and 6b. It can be clearly seen that, while the change in cell potential is indeed measurable by the sensing electrode 151, the amplitude of the signal changes significantly and its form bares only a poor resemblance to the source potential. However, once the potential of the fluid region is controlled in the manner taught by the invention, the amplitude of the recorded signal is largely independent of Z_{couple} and Z_{stray}. The form of the signal is somewhat affected by the ringing response of the readout circuit but this can be corrected by knowing the circuit properties in the manner taught by the invention, and an accurate copy of the internal cell potential can be accurately inferred with high fidelity.

In summary, the invention comprises an active feedback system that solves the basic limitations of prior weakly coupled readout methods by making the measurements insensitive to stray coupling to other elements in the system. When the electrical potential of an object is measured with an electrode that couples to it with high impedance, and the object has electrical coupling to other potentials, then the potential of the electrode differs from that of the object. The invention applies an active feedback signal to regions adjacent to the sensing region in order to make the ratio of the electrode voltage to the object voltage significantly less dependent on the coupling of the object to other potentials.

Thus a benefit of the invention is to make the signal measured by the sense electrode, a more reliable and stable representation of the original source signal in the event that the stray impedance of the object being measured, has a significant and/or variable effect. As discussed, the invention provides for a reliable measurement of the internal cell potential while still allowing a small fluid layer to be present between the cell and sensing electrode. This advance permits the measurement of cells over extended periods of time, over wider frequency ranges, and offers the opportunity for massively parallel measurements of cell activity with little to no human intervention or degradation of the cell caused by the measurement technique itself.

Although described with reference to a preferred embodiment of the invention, it should be readily understood that various changes and/or modifications can be made to the invention without departing from the spirit thereof. For instance, it will be appreciated that this technique can be extended to abiotic cells, which act as if they are biotic cells in the sense that they represent volumes with a changing internal potential and with the possibility of stray coupling or shunts to other elements of the measurement system. In this case, the active feedback technique is used, as above, to increase the electrical isolation of the cell from other sources to of signal and to decrease the sensitivity of the measurement to changes in the level of stray coupling. In general, the invention is only intended to be limited by the scope of the following claims.

I/We claim:

1. A non-invasive measurement system for measuring an electrical potential of a voltage source comprising:
a sensing electrode spaced from the voltage source;
an object placed between the electrode and the voltage source;
a feedback electrode positioned near the sensing electrode;
an amplifier having an input and an output, said input connected to the sensing electrode with a first low resistance connection and the output connected to the feedback electrode with a second low resistance connection.

2. The system of claim 1 wherein the voltage source is within a biological cell located in a nutrient bath including electrolytic fluid.

3. The system of claim 2 wherein the object is a portion of the electrolytic fluid located between the cell and the sensing electrode.

4. The system of claim 1 wherein the sensing electrode is connected to the voltage source by a capacitive connection.

5. The system of claim 1 wherein the feedback electrode is connected to the voltage source by a capacitive connection.

6. The system of claim 1 wherein the feedback electrode has an annular shape and substantially surrounds the sensing electrode thus creating an annular fluid region therebetween.

7. The system of claim 2 wherein the sensing electrode forms a capacitive connection with the object.

8. The system of claim 7 wherein the amplifier has a gain set to compensate for an impedance dividing effect of an impedance of the amplifier and an impedance of a coupling of the sensing electrode to the object, as well as to compensate for a drop in voltage from the feedback electrode to the electrolyte fluid.

9. The system of claim 8 wherein a voltage value of the annular fluid region is substantially equal to a voltage value of the object and an impedance between the object and a stray voltage source is maximized.

10. A system for measuring an electric potential of an object comprising:
a sensing electrode that couples to a potential of an object of interest;
an amplifier connected to the sensing element, said amplifier producing an output proportional to a potential of the sensing element; and
a feedback electrode enabling a potential of the sensing electrode, to be created in a vicinity of the object, wherein an output of the amplifier is coupled to the feedback electrode to enhance a fidelity of a measurement of the potential of the object of interest.

11. The system according to claim 10 further comprising: a grounding element establishing a common voltage reference between a surrounding environment and the amplifier over a bandwidth of interest.

12. The system according to claim 10 in which the potential of the object of interest is generated by a living cell.

13. The system according to claim 12 in which the object of interest is a fluid between the cell and the sensing electrode.

14. The system according to claim 10 in which the object of interest is a confined layer of fluid in a long narrow channel in which the sensing electrode is at one end of the channel.

15. The system according to claim 10 in which the coupling between the sensing electrode and the object of interest in primarily capacitive.

16. The system according to claim 10 in which a coupling between a grounding element and an environment surrounding the object of interest is primarily capacitive.

17. The system according to claim 10 in which a coupling between a grounding element and an environment surrounding of the object of interest in primarily resistive.

18. A method for enhanced fidelity of a measurement of an electric potential of a biological cell located in a nutrient bath comprising:
sensing the electrical potential through an object with a sensing electrode; and
setting a voltage of an electrode solution in an annular space surrounding the sensing electrode substantially equal to a voltage of the object to maximize an impedance between the object and another source of voltage.

19. The method of claim 18, further comprising:
connecting an amplifier to the sensing electrode; and
setting a gain of the amplifier to compensate for an impedance dividing effect of an impedance of the amplifier and an impedance of a capacitive coupling of the sensing electrode to the object.

20. The method of claim 18, further comprising: creating a potential of the sensing electrode in a vicinity of the object through a feedback arrangement.
